(19) United States
(12) Patent Application Publication
(10) Pub. No.: US 2011/0188528 A1
(43) Pub. Date: Aug. 4, 2011

(54) High Injection Efficiency Polar and Non-Polar III-Nitrides Light Emitters

(75) Inventors: Mikhail V. Kisin, Carlsbad, CA (US); Hussein S. El-Ghoroury, Carlsbad, CA (US)

(73) Assignee: OSTENDO TECHNOLOGIES, INC., Carlsbad, CA (US)

(21) Appl. No.: 13/014,002

(22) Filed: Jan. 26, 2011

Related U.S. Application Data
(60) Provisional application No. 61/301,523, filed on Feb. 4, 2010.

(51) Int. Cl. H01S 5/343; H01L 33/06

(52) U.S. Cl. 372/44.011; 257/13; 257/E33.008

(57) ABSTRACT

Injection efficiency in both polar and non-polar III-nitride light-emitting structures is strongly deteriorated by inhomogeneous population of different quantum wells (QWs) in multiple QW (MQW) active region of the emitter. Inhomogeneous QW population becomes stronger in long-wavelength emitters with deeper active QWs. In both polar and non-polar structures, indium and/or aluminum incorporation into optical waveguide layers and/or barrier layers of the active region, depending on the desired wavelength of the light to be emitted, improves the uniformity of QW population and increases the structure injection efficiency.

### CROSS-REFERENCE TO RELATED APPLICATIONS

This application claims the benefit of U.S. Provisional Patent Application No. 61/301,523 filed Feb. 4, 2010.

### BACKGROUND OF THE INVENTION

1. Field of the Invention

The present invention relates to the injection efficiency of polar and non-polar III-nitride light emitters; i.e., light emitting diodes and laser diodes.

2. Prior Art

Expectations of non-polar technology advances in III-nitride light emitters are very high (see Wetzel et al., “RPI starts to extinguish the green gap,” Compound Semiconductors, vol. 15, pp. 21-23, 2009). The absence of internal polarization fields and lack of related quantum-confined Stark effect in non-polar structures imply better transport and optical characteristics of non-polar devices (see Waltereit et al., “Nitride semiconductors free of electrostatic fields for efficient white light-emitting diodes,” Nature, vol. 406, pp. 865-868, 2000). Non-polar templates are expected to be especially favorable for light emitters operating in the green-yellow spectral region where the higher indium incorporation in active quantum wells (QWs) is necessary and, therefore, higher strain-induced polarization would inhibit the characteristics of polar devices. However, the green laser diodes were first implemented practically simultaneously on both polar (see Miyoshi et al., “510-515 nm InGaN-Based Green Laser Diodes on c-Plane GaN Substrate,” Applied Physics Express, vol. 2, p. 062201, 2009; Queren et al., “500 nm electrically driven InGaN based laser diodes,” Applied Physics Letters, vol. 94, pp. 081119-3, 2009; and Avramescu et al., “InGaN laser diodes with 50 mW output power emitting at 515 nm,” Applied Physics Letters, vol. 95, pp. 071103-3, 2009) and non-polar (see Okamoto et al., “Nonpolar m-plane InGaN multiple quantum well laser diodes with a lasing wavelength of 499.8 nm,” Applied Physics Letters, vol. 94, pp. 071105-3, 2009) crystal orientation templates without any substantial advantages of the later which indicates the existence of a common drawback for III-nitride polar and nonpolar light-emitting structures.

### BRIEF DESCRIPTION OF THE DRAWINGS

The invention is illustrated by way of example, and not by way of limitation, in the figures of the accompanying drawings in which like reference numerals refer to similar elements.

FIG. 1 illustrates the general structure of the device. Inset details the layout of 3-QW active region.

FIG. 2 illustrates conduction and valence band profiles in 3-QW active regions of typical polar and non-polar MQW light emitting device structures without indium in the waveguide layers at the same injection level. Dashed lines indicate positions of the electron and hole quasi-Fermi levels.

FIG. 3 illustrates the quantum well residual charges in modeled 3-QW polar (C1) and non-polar (M1) light emitting device structures without indium in waveguide layers.

FIG. 4 illustrates the electron and hole populations of active quantum wells as function of injection current density in typical polar (C1) and non-polar (M1) light emitting device structures without indium in waveguide layers.

FIG. 5 illustrates the nominal energy band profiles of the active region of the III-nitride light emitting device of this invention with indium incorporation in its waveguide and barrier layers (structure M3). Dashed lines indicate band profiles in the device without indium incorporation in waveguide and barrier layers (structure M1).

FIG. 6 illustrates the result of 5% (structure M2) and 10% (structure M3) indium incorporation into waveguide and barrier layers of non-polar III-nitride light emitting device on the inhomogeneity of electron and hole populations of active quantum wells of the modeled devices.

### DETAILED DESCRIPTION OF THE PREFERRED EMBODIMENTS

References in the following detailed description of the present invention to “one embodiment” or “an embodiment” means that a particular feature, structure, or characteristics described in connection with the embodiment is included in at least one embodiment of the invention. The appearances of the phrase “in one embodiment” in various places in this detailed description are not necessarily all referring to the same embodiment.

High level of optical and electrical losses in existing III-nitride light-emitting structures necessitates multiple-QW (MQW) design of the active region. In polar structures, strong built-in spontaneous and piezo-polarization fields create conditions for inhomogeneous population of different QWs with P-side QW dominating the optical emission (see David et al., “Carrier distribution in (0001)InGaN/GaN multiple quantum well light-emitting diodes,” Applied Physics Letters, vol. 92, pp. 053502-3, 2008; Liu et al., “Barrier effect on hole transport and carrier distribution in InGaN/GaN multiple quantum well visible light-emitting diodes,” Applied Physics Letters, vol. 93, pp. 021102-3, 2008; and Xie et al., “On the efficiency droop in InGaN multiple quantum well blue light emitting diodes and its reduction with p-doped quantum well barriers,” Applied Physics Letters, vol. 93, pp. 121107-3, 2008). In laser structures the under-pumped QWs can add their inter-band absorption to the total loss thus increasing the laser threshold. Decreased spatial overlap between the lasing states in polarized QWs causes smaller optical gain and demands more QWs in active region of polar lasers. Taking into account inherently high transparency concentrations in wide-gap III-nitrides, the increased number of QWs would increase the lasing threshold in polar structures even further. This makes non-polar or semi-polar technology an attractive alternative to polar templates. Indeed, in the absence of internal polarization fields, after flat-band condition is reached, the QWs in non-polar active regions should be more uniformly populated thus ensuring lower threshold for non-polar light emitting devices. In this invention, however, we emphasize that even in the absence of internal polarization fields, non-polar MQW structures with high QW indium content (deep QWs) still suffer from the same strongly inhomogeneous QW population under a wide range of injection current. The results shown herein demonstrate that this inhomogeneity is a common feature of both polar and non-polar templates. It is induced by carrier confinement in deep QWs and is self-consistently supported by the residual QW charges. The carrier population non-uniformity increases with the QW depth and, therefore, becomes more pronounced in the longer-wavelength emitters. This invention demonstrates that indium incorporation into waveguide and barrier layers improves the QW injection uniformity in both polar and nonpolar III-nitride emitters by making the active QWs effectively shallower. The optimum composition of the waveguide and barrier layers with enhanced indium incorporation, depending on the desired emission wavelength, can also include aluminum for strain management. In III-nitride structures without indium, optimum level of aluminum incorporation into waveguide and barrier layers should be maintained to ensure shallow active QWs and uniform QW injection.

Given the aforementioned drawbacks of current III-nitride light emitting devices, overcoming such weaknesses is certain to have a significant commercial value. It is therefore the objective of this invention to provide a III-nitride light emitting device structure comprising multiple quantum wells and incorporating optimum indium and/or aluminum concentrations into its waveguide layers and/or barrier layers of the device active region. Optimum indium and/or aluminum incorporation into waveguide and barrier layers of the III-nitride light emitting device improves the injection uniformity of the active QWs which results in overall higher injection efficiency of the structure, lower threshold current for laser diodes and higher external efficiency for light-emitting diodes. Additional objectives and advantages of this invention will become apparent from the following detailed description of a preferred embodiment thereof that proceeds with reference to the accompanying drawings.

A III-nitride multiple quantum well (MQW) light emitting device having indium and/or aluminum incorporated in its waveguide layers and active region barrier layers is described herein. In the following description, for the purpose of explanation, numerous specific details are set forth in order to provide a thorough understanding of the invention. It will be apparent, however, to one skilled in the art that the invention can be practiced with different specific details. In other instance, structures and devices are shown in block diagram form in order to avoid obscuring the invention.

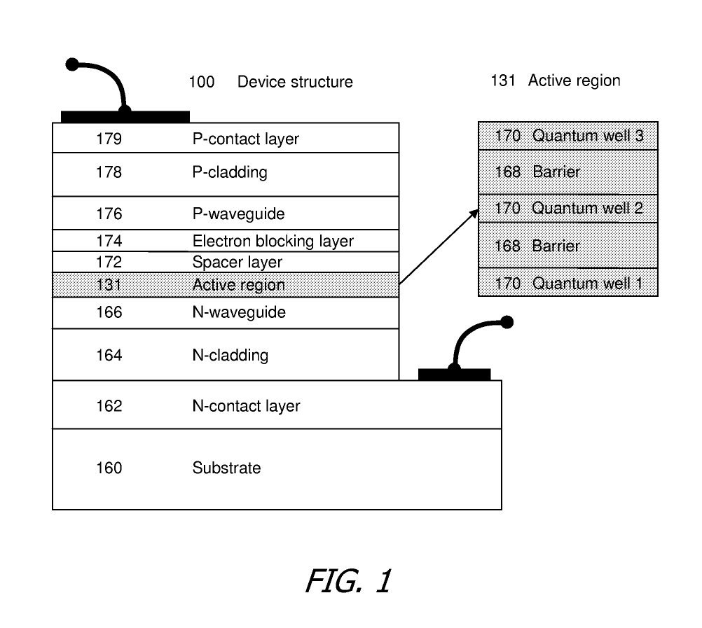

FIG. 1 illustrates an exemplary embodiment of the multilayer cross section of the III-nitride light emitting semiconductor device 100 of this invention. As illustrated in FIG. 1, the preferred embodiment of the III-nitride light emitting device 100 of this invention is a semiconductor diode structure with MQW active region grown on a gallium nitride (GaN) substrate by using well-known epitaxial deposition process commonly referred to as metal-organic chemical vapor deposition (MOCVD). Other deposition processes such as liquid phase epitaxy (LPE), molecular beam epitaxy (MBE), metal organic vapor phase epitaxy (MOVPE), hydride vapor phase epitaxy (HVPE), hydride metal organic vapor phase epitaxy (H-MOVPE) or other known crystal growth processes can also be used as well as other substrate materials can be employed. The desired wavelength and other pertinent characteristics of the light emitted by the exemplary embodiment 100 of the light emitting device would be achieved by selecting the appropriate values of several design parameters of the multilayer structure, including but not limited to, the III-nitride alloy compositions InₓGa₁₋ₓN, Al_{y}Ga_{1-y}N and Al_{y}InₓGa_{1-x-y}N used in the active region layers, the number of quantum well layers, the width of the quantum well layers, and the width of the barrier layers separating the quantum well layers in the MQW active region. The design parameters of the exemplary embodiment of the multilayer semiconductor structure are selected such that the light emitted by the light emitting device 100 would have a dominant wavelength of 450 nm. However, a person skilled in the art would know how to select the aforementioned parameters for the multilayer structure of FIG. 1 to achieve a different wavelength either shorter or longer than the wavelength that can be achieved through the selection of the design parameters of the exemplary embodiment of the multilayer semiconductor structure of FIG. 1.

As illustrated in FIG. 1 the multilayer semiconductor structure 100 includes an n-contact layer 162 of Si-doped GaN of thickness 100-nm doped at a level 6×10¹⁸ cm⁻³ which is grown on a thick GaN substrate template 160 having the desired crystal orientation; i.e., either polar, semi-polar or non-polar. Although the substrate 160 and n-contact layer 162 in a typical III-nitride device structure is typically GaN, indium-gallium-nitride (InₓGa₁₋ₓN) or aluminum-indium-gallium-nitride (Al_{y}InₓGa_{1-x-y}N) material alloys can be used for the substrate 160 and n-contact layer 162 of the exemplary embodiment of the multilayer semiconductor structure of FIG. 1. Upon the n-contact layer 162 is deposited the cladding layer 164 of n-type of Al_{y}Ga_{1-y}N/GaN superlattice (SL) which would typically be 500-nm thick and have Si doping of 2×10¹⁸ cm⁻³. InₓGa₁₋ₓN and Al_{y}InₓGa_{1-x-y}N material alloys could also be used for the cladding layer 164. Upon the cladding layer 164 is deposited a 100-nm thick n-type GaN waveguide layer 166 which would typically be Si doped at a level of 10¹⁸ cm⁻³. InₓGa₁₋ₓN and Al_{y}InₓGa_{1-x-y}N material alloys could also be used for the waveguide layer 166. Upon the waveguide layer 166 is deposited the active region 131 of the light emitting device structure 100 which is comprised of multiple In_{0.2}Ga_{0.8}N QW layers 170 separated by the InₓGa₁₋ₓN barrier layers 168. InₓGa₁₋ₓN or Al_{y}InₓGa_{1-x-y}N material alloys could also be used for the QW layers 170 and/or barrier layers 168 in order to realize the desired bandgap values in these layers. QW layers 170 and barrier layer 168 can be either doped or undoped to achieve optimum performance of the light emitting device 100. The thickness of the QW layers 170 and barrier layers 168 are selected to be 3-nm and 8-nm; respectively, however the thickness of these layers could be increased or decreased depending upon the crystal orientation used and in order to tune the emission characteristics of the light emitting device 100 to the desired emission wavelength. In the exemplary embodiment of the multilayer semiconductor structure of FIG. 1 the selected thickness of the QW layers 170 and barrier layers 168 and the non-zero value of x=0.2 for the indium incorporation within the QW layers 170 was selected such that the light emitted by the light emitting device 100 would have a dominant wavelength of 450 nm.

Although FIG. 1 shows the active region 131 of the light emitting device 100 being comprised of three QWs, the number of QWs used could be increased or decreased in order to fine tune the operational characteristics of the light emitting device 100. Furthermore, the active region 131 of the light emitting device 100 could also be comprised of multiplicity of quantum wires or quantum dots instead of quantum wells.

Above the active region 131 is deposited a 10-nm thick GaN spacer layer 172 which can be either doped or undoped. Upon spacer layer 172 is deposited a 15-nm thick Al_{y}Ga_{1-y}N electron blocking layer 174 which is usually p-doped by magnesium (Mg) with doping level of approximately 10×10¹⁸ cm⁻³. InₓGa₁₋ₓN or Al_{y}InₓGa_{1-x-y}N material alloys could also be used for the spacer layer 172 and electron blocking layer 174. The electron blocker layer 174 is incorporated in order to reduce the electron leakage current, which would increase the threshold current and the operating temperature of the light emitting device 100.

Above the electron blocker layer 174 is deposited a 100-nm thick p-type GaN waveguide layer 176 which would typically be magnesium (Mg) doped at a level of 10¹⁹ cm⁻³. Upon the waveguide layer 176 is deposited a 400-nm thick p-type Al_{y}Ga_{1-y}N/GaN superlattice (SL) cladding layer 178 which would typically be magnesium (Mg) doped at a level of 10¹⁹ cm⁻³. Upon the cladding layer 178 is deposited a 50-nm thick p-type GaN contact layer 179 which would typically be magnesium doped at a level of 10¹⁹ cm⁻³. InₓGa₁₋ₓN and Al_{y}InₓGa_{1-x-y}N material alloys could also be used for the waveguide layer 176, cladding layer 178, and contact layer 179.

The multilayer 164-166-131-172-174-176 is known to a person skilled in the art as the optical resonator or optical confinement region of the light emitting device 100 within which the light generated by the MQW active region 131 would be confined. Such optical confinement structures are typically used to provide either the feedback required in the implementation of laser diode devices or the light recycling in resonant cavity light emitting diode devices.

The anticipated benefits of the III-nitride light emitting device structure 100 of this invention is illustrated by means of simulation. For carrier transport simulation traditional drift-diffusion approximation is widely accepted for III-nitride device modeling (see J. Piprek, Optoelectronic devices: advanced simulation and analysis. New York: Springer, 2005; and J. Piprek, “Nitride Semiconductor Devices: Principles and Simulation,” Berlin: Wiley-VCH Verlag GmbH, 2007, p. 496). In our simulation, special attention was paid to the detailed modeling of carrier confinement in active QWs. III-nitride QW subband structure and intra-well charge distribution were calculated self-consistently using multi-band Hamiltonian with strain-induced deformation potentials and valence band mixing terms (see M. V. Kisin, “Modeling of the Quantum Well and Cascade Semiconductor Lasers using 8-Band Schrödinger and Poisson Equation System,” in COMSOL Conference 2007, Newton, Mass., USA, 2007, pp. 489-493). The device simulation employed allows modeling of III-nitride QWs grown in arbitrary crystallographic orientation including polar and non-polar templates (see Kisin et al., “Modeling of III-Nitride Quantum Wells with Arbitrary Crystallographic Orientation for Nitride-Based Photonics,” in COMSOL Conference 2008, Boston, Mass., USA, 2008). Simulated QW characteristics take into account thermal carrier redistribution between QW subbands and intra-QW screening of internal polarization fields (see Kisin et al., “Optical characteristics of III-nitride quantum wells with different crystallographic orientations,” Journal of Applied Physics, vol. 105, pp. 013112-5, 2009; and Kisin et al., “Optimum quantum well width for III-nitride nonpolar and semipolar laser diodes,” Applied Physics Letters, vol. 94, pp. 021108-3, 2009). COMSOL-based programming then allows self-consistent incorporation of the injection dependence of the QW confined energy levels, sub-band density of states (DOS) parameters, screened polarization fields and QW radiative recombination rates into the transport modeling (see Kisin et al., “Software Package for Modeling III-Nitride Quantum-Well Laser Diodes and Light Emitting Devices,” in COMSOL Conference 2009, Boston, Mass., USA, 2009).

Specifically, the modeled benchmark device structures, polar C-1 and nonpolar M-1, comprise three In_{0.2}Ga_{0.8}0N QWs 3 nm and 2.5 nm wide for non-polar and polar crystal orientation; respectively, two n-doped GaN barriers each being 8 nm in width, and 10 nm wide undoped GaN spacer layer separating MQW layers described above from a 15 nm wide Al_{0.15}Ga_{0.85}N P-doped electron-blocking layer (EBL). The MQW active region is sandwiched between 100 nm N- and P-doped GaN waveguide layers. All microscopic parameters for modeling have been extracted from the same source (see Vurgaftman et al., “Electron band structure parameters,” in Nitride semiconductor devices: Principles and simulation, J. Piprek, Ed.: Wiley, New York, 2007, pp. 13-48]), except for the higher value of InGaN fundamental band-gap bowing coefficient, 2.8 eV, adopted from (see Moret et al., “Optical, structural investigations and band-gap bowing parameter of GaInN alloys,” Journal of Crystal Growth, vol. 311, pp. 2795-2797, 2009). The valence to conduction band offsets ratio is 3:7 for all interfaces. For all the modeled device structures the pseudomorphic growth of the active region was assumed with QW layers elastically strained to fit the lattice of the GaN waveguide material. None of the accepted specific material parameter values is crucial for the modeling results; the QW population inhomogeneity demonstrated in our modeling stems exclusively from the presence of deep QWs in the active region, which is a characteristic feature of all long wavelength III-nitride light emitters.

Four light emitting device structures having substantially the same multilayer structure as that illustrated in FIG. 1 were modeled for comparison purposes in order to demonstrate the benefits of this invention. The first light emitting device structure (designated C-1) was assumed to be grown on c-plane (polar) crystal orientation while the second the third and the fourth device structures (designated M-1, M-2, and M-3) were assumed to have been grown on m-plane (non-polar) crystal orientation. The light emitting device structure layouts, C-1 and M-1, are compared with light emitting device structures M-2 and M-3 of this invention that incorporate indium in the waveguide and barrier layers (see Table 1). Detailed comparison of subband structures and radiative characteristics of c-plane (polar) and m-plane (non-polar) grown MQWs can be found in (see Kisin et al., “Optical characteristics of III-nitride quantum wells with different crystallographic orientations,” Journal of Applied Physics, vol. 105, pp. 013112-5, 2009; and Kisin et al., “Optimum quantum well width for III-nitride nonpolar and semipolar laser diodes,” Applied Physics Letters, vol. 94, pp. 021108-3, 2009). Dependences of confined energy levels, subband density of states (DOS), radiative recombination rates, and screened polarization fields on the MQW injection level, obtained during microscopic modeling, were used in transport modeling through COMSOL inter-program data interpolation procedures to ensure realistic simulation of the MQW population dynamics. Some of the QW parameters are presented in Table 1 for the polar (C-1) and the non-polar (M-1, M-2, and M-3) device structures. Effective bulk parameters used in modeling include radiative constant B=0.2×10⁻¹⁰ cm³/s, carrier nonradiative SRH-recombination lifetimes tₑ=10 ns and tₕ=20 ns, and Auger recombination coefficient C=10⁻³° cm⁶/s. These values are very close to typical experimental estimates (see Zhang et al., “Direct measurement of Auger recombination in In0.1Ga0.9N/GaN quantum wells and its impact on the efficiency of In0.1 Ga0.9N/GaN multiple quantum well light emitting diodes,” Applied Physics Letters, vol. 95, pp. 201108-3, 2009). Again, it should be emphasize that none of the above parameters are crucial for realizing the benefits of this invention, which are primarily determined by strong carrier confinement in deep III-nitride MQWs.

TABLE 1

| | Polar | Non-Polar | | |
|---|---|---|---|---|
| QW parameter | C-1 | M-1 | M-2 | M-3 |
| QW material band gap | 2.725 | 2.618 | 2.618 | 2.618 |
| (300K, with strain) in eV | | | | |
| Waveguide Indium (%) | 0 | 0 | 5 | 10 |
| QW band offsets (Δc/Δv) | 498/214 | 573/246 | 381/163 | 273/117 |
| in meV | | | | |
| Main optical transition | 2.647 | 2.748 | 2.733 | 2.730 |
| c1-h1 in eV | | | | |
| Emission wavelength | 468 | 451 | 454 | 454 |
| in nm | | | | |

Essential Parameters of Modeled Polar and Non-Polar MQW Light Emitting Structures.

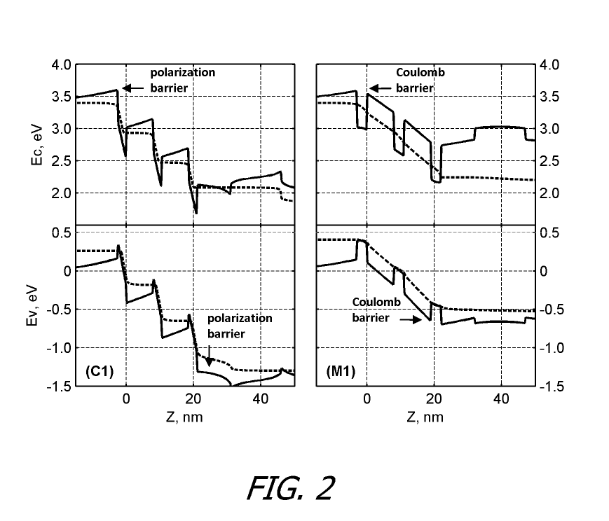

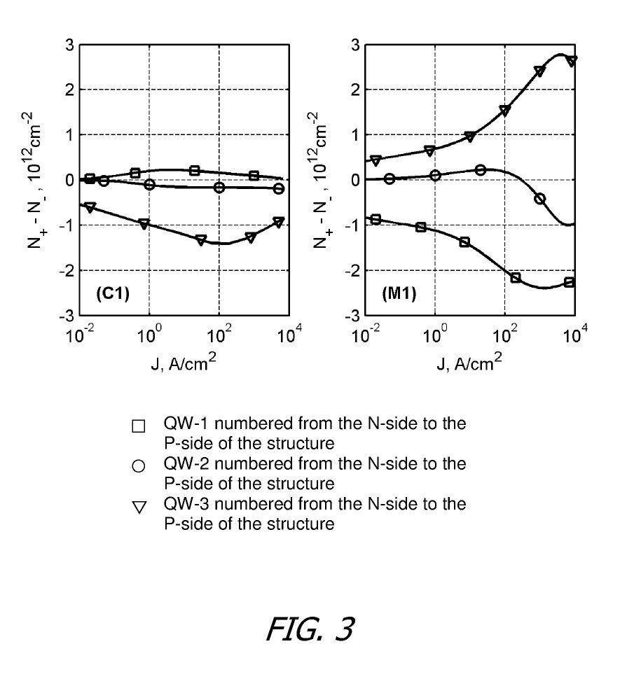

FIG. 2 compares active region band profiles in benchmark device structures C-1 and M-1 calculated at a high injection level of 1.5 kA/cm². It is important that, even at such a high injection level the flat-band condition is not achieved in non-polar structure M1. This is in spite of the fact that typical adverse features of polar structure C1, such as polarization inter-well potential barriers and strong carrier accumulation in polarization-induced potential pockets on both sides of EBL, are absent in device structure M-1. Instead, strong Coulomb barrier due to negative residual charge of the extreme N-side QW is characteristic of non-polar structure M-1 which provides for strong internal field in the active region of non-polar structure; see FIG. 2 structure M-1. For comparable level of injection, the internal field in the active region of non-polar structure M-1 is quite comparable to the one in polar structure C-1. The internal field in the active region of non-polar structure M-1 is supported by opposite charges of the extreme N-side quantum well, designated as QW1 (negative), and the extreme P-side quantum well, designated as QW3 (positive); see FIG. 3. Note that in polar structure C1 the QW charges are opposite. The QWs remain charged even at very high injection current density, when strong carrier overflow comes into play. The typical values of injection levels, when overflow builds up, are about 1 kA/cm² for polar structure (C-1) and 15 kA/cm² for non-polar structure (M-1). The inferior characteristics of the polar structure (C-1) are explained by EBL degradation due to charge accumulation at EBL boundaries; see FIG. 1. Modeling of both structures without EBL confirms that carrier overflow is irrelevant for observed bending of band profiles in active region: although in a non-EBL structure the leakage starts at lower injection, the active region built-in field for a given current density remains practically the same.

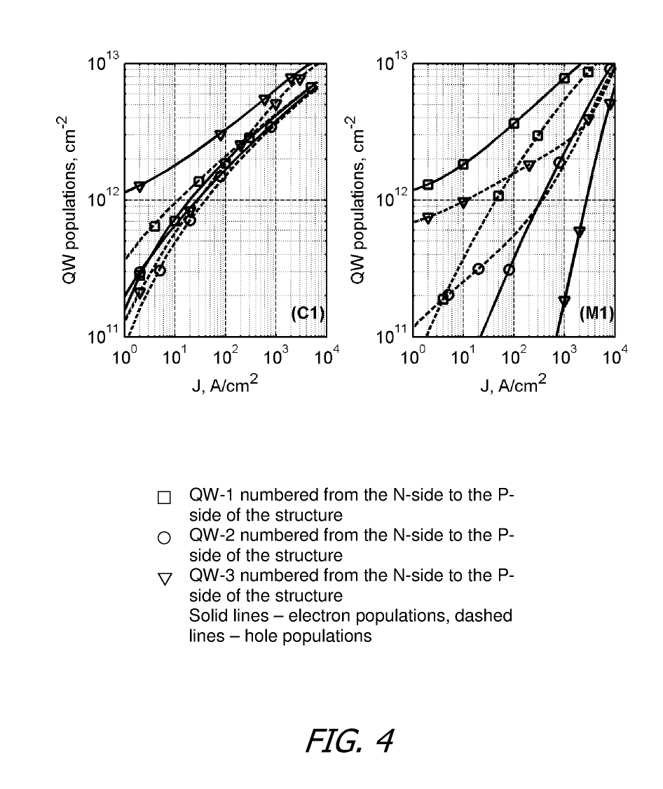

The MQW populations naturally tend to converge with increased injection level (i.e., electrical bias). FIG. 4 shows that in polar structure C-1 such convergence starts at a lower injection level of approximately 10 A/cm², however, the relative population of the extreme P-side QW3 prevails up to the very high injection level in excess of 10 kA/cm². In non-polar structure M1 the inhomogeneity of QW populations remains remarkably strong in a wider range of injection current and is dominated by extreme N-side QW1.

Modeling of QW structures with different QW widths and compositions reveals that the most important factors causing the inhomogeneity of QW population are the depths of electron and hole QWs; details of intra-QW screening, intersubband carrier redistribution, radiative and non-radiative recombination rates, variations in layer doping and carrier mobility proved to be of secondary importance. Our modeling shows that, with sufficient carrier confinement occurring when the MQW depth is in excess of 100 meV for holes and 200 meV for electrons, the active region MQWs of our benchmark layouts C-1 and M-1 are always non-uniformly populated. By varying the band offset ratio, the modeling also indicates that stronger hole confinement and/or weaker electron confinement make population of P-side QW dominant, whilst stronger electron confinement and/or weaker hole confinement provide for dominance of extreme N-side QW.

The modeling results can be readily explained by self-consistent action of the residual MQW charges. In polar structure C-1, due to the effect of the internal polarization fields, the MQWs are effectively shallower and thermal escape of electrons into the waveguide layers is more efficient. This facilitates subsequent drift-diffusive transport of the electrons toward the p-side QW, while the hole injection in polar structure is strongly restrained by EBL; see FIG. 2(C-1). Strong electron accumulation at the spacer-EBL interface also supports the dominance of P-side QW. In non-polar structures of the same compositions, the MQWs are effectively deeper. This curbs the electron escape into waveguide and prevents the electron drift to P-side QW. On the other hand, the hole injection through non-polar EBL is more efficient; see FIG. 2(M-1). This facilitates the hole transport through the structure toward the negatively charged N-side QW and enhances its population. At very high injection levels, however, the electron transport through the waveguide becomes sufficient and P-side MQW regains the dominance.

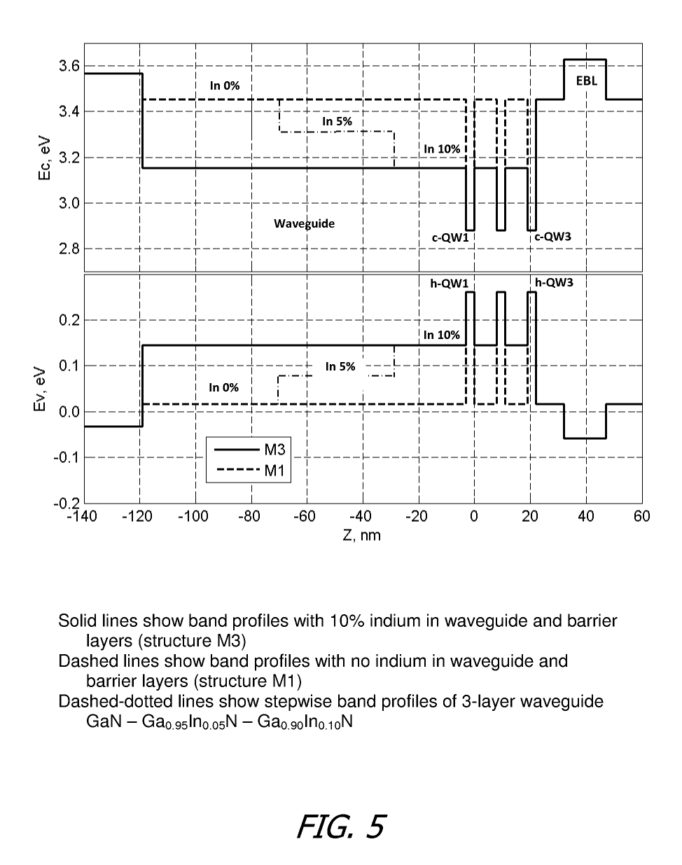

The features of the active region design which affect the carrier confinement also affect the MQW population uniformity. In non-polar structures, for instance, the use of wider QWs improves the optical mode confinement and allows reaching longer wavelength emission, but simultaneously, makes the structure more vulnerable to inhomogeneous QW injection. Our modeling shows that inhomogeneous injection drawback can be compensated in accordance with the preferred embodiment of this invention by incorporating indium into waveguide and/or barrier layers, which effectively acts to decrease the MQW depth and carrier confinement. FIG. 5 illustrates the nominal energy band profiles (without electrical bias and space-charge electric fields) of the preferred embodiment of the III-nitride light emitting device 100 of this invention. As illustrated in FIG. 5, the incorporation of indium into the light emitting structure waveguide layer and barrier layers ensures the realization of shallower quantum wells. The attainment of shallower QWs allows the light emitting device structure 100 of this invention when implemented in non-polar crystal orientation to achieve charge carrier population uniformity within its MQW and, consequently, higher injection efficiency and, in laser diode, the lower lasing threshold.

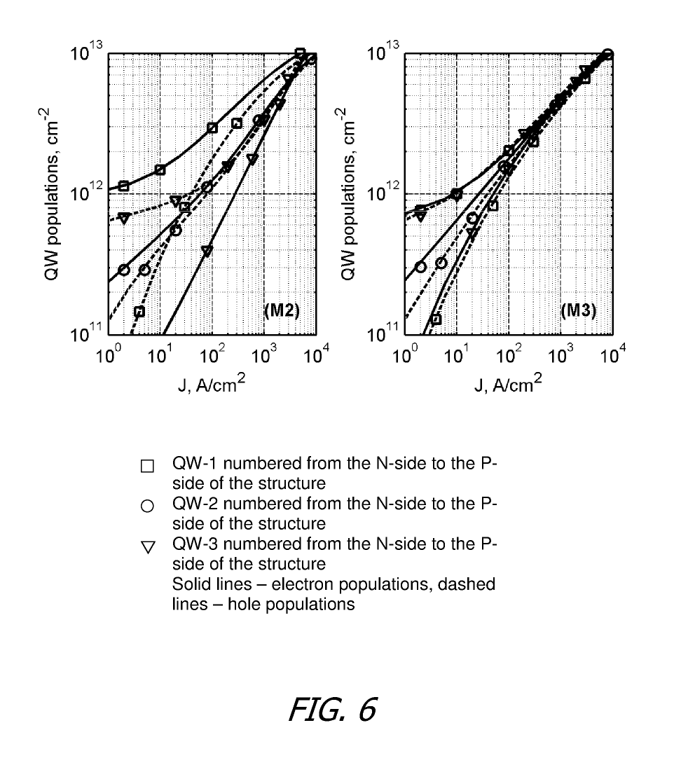

FIG. 6 shows the effect of indium incorporation into waveguide and barrier layers of non-polar structures M-2 and M-3 of the light emitting device 100 of this invention, which features 5% (M-2) and 10% (M-3) indium incorporation into N-waveguide and barrier layers. It is important to note that the uniform distribution of charge carriers (electron and holes) among the active MQWs in structures M-2 and M-3 provides for a higher injection efficiency of the structure and higher optical output of the light emitting device.

Following the same trend, the use of narrower QWs width can also improve the uniformity of MQW population. In wider QWs the carrier confinement is stronger and the carrier energy levels are located deeper in energy. On the contrary, the narrow QWs are effectively shallower and carrier confinement in narrow QWs is weaker. Use of narrow QWs, therefore, complements the indium incorporation into waveguide layers with the purpose to achieve uniform population of active QWs. QW width, however, is a subject of trade-off between uniformity of QW populations and thermal depopulation of shallow QWs; the optimum width for III-nitride light emitting MQW structures should not exceed 5 nm (see Kisin et al., “Optimum quantum well width for III-nitride nonpolar and semipolar laser diodes,” Applied Physics Letters, vol. 94, pp. 021108-3, 2009). It is relevant to note that narrowing of the QW is more efficient in non-polar structures; in a polar QW the efficient QW width is already smaller than the nominal value due to effect of the internal polarization field, and, correspondingly, the carrier confinement is weaker. For instance, our modeling shows that changing QW width to 2 nm does not produce any noticeable changes of relative QW populations in structure C-1 while a similar change of QW width in structure M-1 brings the MQW populations to convergence at much lower injection level of 100 A/cm².

An added advantage of one of the primary features of the III-nitride light emitting device 100 of this invention; namely, the incorporation of indium into the waveguide layer 166, is that such a feature would facilitate the higher indium intake (meaning higher level of indium incorporation) into the MQW layers 170. In typical III-nitride light emitting devices, such as device structure C-1 of Table 1, the transition from no indium (meaning zero value of “x”) being incorporated in the waveguide layer 166 to a finite ratio “x” of indium in the first quantum well layer QW-1 170 could cause a significant enough lattice mismatch between the two layers that would prevent effective and uniform indium incorporation at the desired incorporation ratio “x” into the MQW 170. Such an effect has been known to prevent the incorporation of high indium levels within the MQW, which would prevent the attainment of longer wavelength light emission from the III-nitride light emitting device. Beside the advantage of achieving higher injection efficiency as described earlier, the incorporation of indium into the waveguide layer 166 would result in a reduction of the crystal lattice mismatch between the waveguide layer and the QW-1 layer 170, which would as a result facilitate the effective and uniform incorporation of higher ratio “x” of indium into the MQW layers 170 of the III-nitride light emitting device 100 of this invention. The attainment of high ratio “x” of indium incorporation into the MQW layers 170 is therefore facilitated by the incorporation of indium into the waveguide layer 166 whereby the later is achieved either as a gradual or stepwise discrete increase in the ratio “x” of indium across the waveguide layer 166 as illustrated in FIG. 5.

In summary, it is shown through numerical simulation and modeling that the light emitting device structures of this invention which have indium incorporated into waveguide/barrier layers of the device structure (meaning the indium incorporation ratio “x” is non-zero) will improve the charge carrier population uniformity which will subsequently lead to the realization of high injection efficiency and low threshold III-nitride light emitting devices.

In the forgoing detailed description, the present invention has been described with reference to specific embodiments thereof. It will, however, be evident that various modifications and changes can be made thereto without departing from the broader spirit and scope of the invention. The design details and drawings are, accordingly, to be regarded in an illustrative rather than a restrictive sense. Skilled persons will recognize that portions of this invention may be implemented differently than the implementation described above for the preferred embodiment. For example, skilled persons will appreciate that the III-nitride light emitting device structures comprising multiple quantum wells with optimum indium and/or aluminum incorporation in their waveguide and barrier layers of this invention can be implemented with numerous variations to the number of quantum wells, the width of the quantum wells, the width of the barriers, the indium and/or aluminum incorporation ratios in the waveguide layers, the indium and/or aluminum incorporation ratios in the barrier layers, the composition of the electron blocking layer (EBL), the doping levels of the p-doped and n-doped layers and the thickness of the waveguide and cladding layers of the device.

It should be noted that in the foregoing description, the exemplary embodiment used Indium as the primary component in the alloys to achieve the desired results. This choice was primarily to achieve a desired wavelength of light to be emitted. Note however that the present invention may be used in light emitting devices that emit at least in the range from infrared to ultraviolet. Accordingly, particularly for blue through ultraviolet, aluminum may be the primary component for obtaining the desired band-gaps. Thus in general, embodiments of the present invention will use the III-nitride alloys InₓGa₁₋ₓN, AlGa_{1-y}N and/or AlInₓGa_{1-x-y}N being the most general expression for these alloys provided x and/or y are allowed to be zero. The comparative performance of devices of the present invention is determined by comparing the performance of a light emitting device using AlInₓGa_{1-x-y}N for the N-doped waveguide and barrier layers, where x and/or y is not zero, with the performance of a corresponding light emitting device having x and y both equal to zero. In that regard, it is conceivable that the N-doped waveguide could have a band-gap gradually or stepwise graded from zero values of x and y (i.e., GaN) to AlInₓGa_{1-x-y}N, where either or both x and y are non-zero, adjacent the active multiple quantum well region. In that regard, it may be seen from FIG. 5 that preferably the band-gap of the N-type waveguide is approximately the same as the band-gap of the barrier layers in the multiple quantum well region, though in general that is not a limitation of the invention.

Skilled persons will further recognize that many changes may be made to the details of the aforementioned embodiments of this invention without departing from the underlying principles and teachings thereof. The scope of the present invention should, therefore, be determined only by the following claims.

What is claimed is:

1. A solid state light emitting device fabricated using III-nitride alloy materials on either polar, semi-polar or non-polar crystal orientation and comprised of multiple layers grouped into a P-doped waveguide layer, an active multiple quantum well region, an electron blocking layer and an N-doped waveguide region, the multiple active quantum well region being further comprised of multiple layers to form multiple quantum wells and barrier layers, the band-gaps associated with the N-doped waveguide region and the barrier layers being realized through the incorporation of indium and/or aluminum in said layers.

2. The solid state light emitting device of claim 1 wherein the amounts of indium and/or aluminum in the N-doped waveguide region and the barrier layers being selected to decrease the band-gap differences between the band-gaps of the multiple quantum wells and the N-doped waveguide region and the barrier layers.

3. The solid state light emitting device of claim 2 wherein the band-gaps of the barrier layers are approximately the same as the band-gap of the N-doped waveguide layer adjacent the multiple active quantum well region.

4. The solid state light emitting device of claim 1 wherein the active multiple quantum well region and the N-doped waveguide layer are fabricated using the ternary semiconductor alloy materials InₓGa₁₋ₓN and AlGa_{1-y}N or quaternary semiconductor alloy materials AlInₓGa_{1-y-x}N, the subscripts “x” and “y” representing the alloy compositions used in the multiple quantum wells, barrier and N-doped waveguide layer.

5. The solid state light emitting device of claim 4 wherein the values of “x” and “y” for the alloys within the multiple quantum wells have been selected to allow the solid state light emitting device of claim 1 to emit light within a desired range of wavelengths.

6. The solid state light emitting device of claim 4 wherein the values of “x” and “y” for the alloys within the barrier and waveguide layers have been selected to provide uniform carrier distribution in the multiple quantum wells.

7. The solid state light emitting device of claim 4 wherein the values of “x” and “y” for the alloys within the barrier layers have been selected for the attainment of uniform carrier population among the multiple quantum wells to provide a higher injection efficiency than when the values of “x” and “y” are both zero.

8. The solid state light emitting device of claim 4 wherein the values of “x” and “y” for the alloys within the N-doped waveguide region have been selected for the attainment of uniform carrier population among the multiple quantum wells to provide a higher injection efficiency than when the compositions “x” and “y” are both zero.

9. The solid state light emitting device of claim 4 wherein “x” and/or “y” for the alloys within the N-doped waveguide layer have been selected to vary gradually over a range of increasing non-zero values to for lattice matching with the multiple quantum wells.

10. The solid state light emitting device of claim 4 wherein “x” and/or “y” for the alloys within the N-doped waveguide layer have been selected to vary in discrete steps over a range of increasing non-zero values to for lattice matching with the multiple quantum wells.

11. The solid state light emitting device of claim 4 wherein the values of “x” and/or “y” for the alloys within the N-doped waveguide layer have been selected to vary the band-gap within the N-doped waveguide gradually over a range of increasing non-zero values to obtain a band-gap adjacent the multiple active quantum well region that approximately equals the band-gap of the barrier layers.

12. The solid state light emitting device of claim 4 wherein the values of “x” and/or “y” for the alloys within the N-doped waveguide layer have been selected to vary the band-gap within the N-doped waveguide in discrete steps over a range of increasing non-zero values to obtain a band-gap adjacent the multiple active quantum well region that approximately equals the band-gap of the barrier layers.

13. The solid state light emitting device of claim 1 wherein the multiple quantum wells are narrow to provide uniform carrier population within the multiple quantum wells.

14. The solid state light emitting device of claim 1 realized as a high injection efficiency laser diode or light emitting diode device.
